(19) United States
(12) Patent Application Publication
(10) Pub. No.: US 2022/0098224 A1
(43) Pub. Date: Mar. 31, 2022

(54) ORGANOMETALLIC COMPOUNDS

(71) Applicant: Umicore AG & Co. KG, Hanau-Wolfgang (DE)

(72) Inventors: Joerg SUNDERMEYER, Marburg (DE); Henrik SCHUMANN, Weinbach (DE)

(21) Appl. No.: 17/421,272

(22) PCT Filed: Jan. 7, 2020
(86) PCT No.: PCT/EP2020/050167

§ 371 Date: Jul. 7, 2021

(30) Foreign Application Priority Data
Jan. 8, 2019 (EP) 19150816.7

(51) Int. Cl. C07F 15/00; C23C 16/18; C23C 16/455

(52) U.S. Cl. CPC C07F 15/0046; C23C 16/45553; C23C 16/18

(57) ABSTRACT

The invention relates to ruthenium complexes of formula (I): [(arene)RuXL] formula (I) wherein the ruthenium includes the following ligands: (arene) arene, which may be optionally substituted, X H or C1-C8 hydrocarbon group, and L R2N—CR1=NR3, wherein R1 is selected from H, C1-C8 hydrocarbon group, which may be optionally substituted, and —NR4R5, wherein R4 and R5 independently of one another are selected from H and C1-C8 hydrocarbon groups, which may be optionally substituted, R2 and R3 independently of one another are selected from C1-C8 hydrocarbon groups, which may be optionally substituted, wherein R2 and R3 are identical to or different from one another, and R1 may be linked directly to R2, R1 may be linked directly to R3 and/or R2 may be linked directly to R3.

The invention relates to ruthenium complexes which are described by a formula (I). The invention further relates to methods for producing such ruthenium complexes and to the use thereof for depositing ruthenium in CVD processes and ALD processes. The invention further relates to methods in which such ruthenium complexes are used as precursors for producing a ruthenium layer. The invention moreover relates to ruthenium-plated surfaces obtainable by depositing ruthenium on a surface from a gas phase, wherein the gas phase comprises such a ruthenium complex.

### PRIOR ART

Chemical vapor deposition (CVD) processes and atomic layer deposition (ALD) processes are used for coating substrates. A desired material is deposited from the gas phase on a surface of a substrate. In the gas phase, the desired material is typically present in the form of a precursor chemical, briefly referred to also as precursor. Different precursors are used depending on the material to be deposited.

In the prior art, for example metal complexes are used as precursors for metals in general. EP 3 026 055 A1 describes, for example, N amino guanidinate complexes of various metals, which are used inter alia in the production of thin layers, for example by CVD. DE 10 2011 012 515 A1 describes metal complexes with N amino amidinate ligands, which are likewise used in gas-phase thin-film processes, such as CVD.

Ruthenium complexes, among others, are used as precursors for ruthenium in the prior art. In connection with the formation of metal films using metal amidinates, U.S. Pat. No. 7,737,290 B2 discloses a synthesis of tris(N,N′-diisopropylacetamidinato)ruthenium. EP 1 884 517 A1 relates to organometallic compounds which are supposed to be suitable as precursors for CVD and ALD processes. A theoretical example of EP 1 884 517 A1 describes a preparation of (1-dimethylamino)allyl (η⁶-p-cymene)ruthenium diisopropylacetamidinate. The precursor described here is a theoretical preparation of [(p-cymene)RuCl(N,N′-bis-iso-propylaminoacetaminate)].

Further examples of ruthenium complexes as precursors for ruthenium in gas-phase thin-film processes are [(methylcyclopentadienyl)₂Ru], [(dimethylpentadienyl)₂Ru] and [(arene)Ru(1,4-diaza-1,3-butadiene)].

Some of the precursors for ruthenium used in the prior art are still in need of improvement. Some of these precursors have disadvantages, such as low synthetic accessibility, excessively high decomposition temperatures and excessively high incorporation rates of carbon and other impurities in the production of thin layers. In addition, some of the precursors for ruthenium used in the prior art are unsuitable for ALD processes, since a preferred elimination of only a weakly bound ligand of these precursors occurs. Further disadvantages of some precursors are that they are too volatile and/or are not liquid at room temperature.

In an industrial application, it is also of particular interest that as few steps as possible lead to the desired product in the synthesis of precursors for ruthenium. Also, harsh reaction conditions should be avoided. Moreover, the precursors should be obtained in an optimized and as high a yield as possible. It is particularly advantageous if the precursors are stable at room temperature for a long time. In addition, the precursors should also easily withstand even the heating of a storage container for CVD or ALD processes, such as a so-called bubbler, to temperatures up to 100° C. in order to increase the vapor pressure. At further elevated temperatures, however, the precursors should then decompose exothermically under typical conditions of CVD or ALD processes, in particular under elevated temperatures.

### Object of the Invention

The object of the invention is to provide ruthenium complexes which at least partially or, if possible, fully overcome the disadvantages described above.

It is a further object of the invention to provide ruthenium complexes which have the desirable properties described above. The ruthenium complexes should have a high volatility, be as liquid as possible at room temperature and still stable at higher temperatures, but should not have too high decomposition temperatures.

The object of the invention is also to ensure good synthetic accessibility of the ruthenium complexes, in particular via syntheses with few steps. Another object is for the synthesis of the ruthenium complexes to not require any harsh reaction conditions and to give as high yields as possible.

### Disclosure of the Invention

Surprisingly, the objects of the invention are achieved by ruthenium complexes according to the claims.

The invention relates to a ruthenium complex of formula (I):

[(aren)RuXL] formula (I),
the ruthenium complex comprising the following ligands: (arene)=arene which may be optionally substituted,
X=H or C₁-C₈ hydrocarbon radical, and
L=R²N—CR¹═NR³,
   wherein
   R¹ is selected from H, C₁-C₈ hydrocarbon radical, which may be optionally substituted, and —NR⁴R⁵, wherein R⁴ and R⁵ are selected independently of one another from H and C₁-C₈ hydrocarbon radicals, which may be optionally substituted,
   R² and R³ are selected independently of one another from C₁-C₈ hydrocarbon radicals, which may be optionally substituted, wherein R² and R³ are the same or different from one another, and
   R¹ may be linked directly to R², R¹ to R³ and/or R² to R³.

Ruthenium complexes of formula (I) may be volatile and may be liquid at room temperature. Ruthenium complexes of formula (I) may still be stable at higher temperatures and may exhibit no excessive decomposition temperatures. Ruthenium complexes of formula (I) may be represented in high yields over a few steps under mild conditions.

A ruthenium complex of formula (I) is neutral, which is reflected in the absence of a charge indication on the square bracket.

In the complex of formula (I), the ruthenium (Ru) forms the central atom, (arene), X and L form the ligands of the complex.

According to the International Union of Pure and Applied Chemistry, arene means an aromatic hydrocarbon. Arenes include both monocyclic and polycyclic aromatic hydrocarbons. Said aromatic hydrocarbons may be optionally substituted. In the general reaction scheme given below, optional substituents on the ligand (arene) are denoted by (R⁶)ₙ. The index n may preferably be 0, 1, 2, 3, 4, 5 or 6, more preferably 0 or 2, particularly preferably 2. According to the invention, R⁶ is preferably selected from hydrocarbon radicals, hydroxy groups, alkoxy groups, amino groups and halogens, more preferably from hydrocarbon radicals.

Ligand X is either a hydrido ligand (H) or a C₁-C₈ hydrocarbon radical, preferably H or a C₁-C₆ hydrocarbon radical, even more preferably H or a C₁-C₄ hydrocarbon radical.

In the context of the present invention, a hydrocarbon radical refers, as usual, to a radical which is composed exclusively of carbon and hydrogen. In the context of the present invention, a hydrocarbon radical which may be optionally substituted refers to a radical which may have atoms different from carbon and hydrogen (heteroatoms) as substituents.

In the context of the present invention, a C₁-C₈ hydrocarbon radical refers to a hydrocarbon radical having 1 to 8 carbon atoms, i.e. having 1, 2, 3, 4, 5, 6, 7 or 8 carbon atoms. In the context of the present invention, a C₁-C₆ hydrocarbon radical refers to a hydrocarbon radical having 1 to 6 carbon atoms, i.e. having 1, 2, 3, 4, 5 or 6 carbon atoms. In the context of the present invention, a C₁-C₄ hydrocarbon radical refers to a hydrocarbon radical having 1 to 4 carbon atoms, i.e. having 1, 2, 3 or 4 carbon atoms.

In the context of the present invention, a hydrocarbon radical generally refers to a hydrocarbon radical that may be saturated or unsaturated. Saturated hydrocarbon radicals are preferred.

In the context of the present invention, a hydrocarbon radical generally refers to a hydrocarbon radical that may be linear, branched or cyclic. Linear and branched hydrocarbon radicals are preferred.

The ligand designated L is formed by a structure R²N—CR¹═NR³. Formally, this structure is singly negatively charged. The negative charge is delocalized via the two nitrogen atoms having the radicals R² and R³ and the middle carbon atom having the radical R¹. In the complex of formula (I), L preferably forms an electron donor.

In addition to H and C₁ to C₈ hydrocarbon radical, R¹ may also be a radical “—NR⁴R⁵”, i.e. an amino group. R⁴ and R⁵ of the amino group are independently of one another either H or a C₁-C₈ hydrocarbon radical. The amino group “—NR⁴R⁵” may be a primary amino group when both R⁴ and R⁵ are H. The amino group may be a secondary amino group if only one of R⁴ and R⁵ is H. The amino group may be a tertiary amino group if none of R⁴ and R⁵ is H. According to the invention, it is preferred for both R⁴ and R⁵ to be a C₁-C₈ hydrocarbon radical, more preferably both are a C₁-C₆ hydrocarbon radical, even more preferably both are a C₁-C₄ hydrocarbon radical. According to the invention, it is particularly preferred for both R⁴ and R⁵ to be methyl or ethyl, and more preferred for both to be methyl.

The structure R²N—CR¹═NR³ may have cyclic groups. For example, CR¹ and R²N together may be part of a cyclic group if R¹ is directly linked to R². Accordingly, CR¹ and NR³ together may be part of a cyclic group if R¹ is directly linked to R³. Finally, R²N and NR³ together may be part of a cyclic group if R² is directly linked to R³. Directly linked means that no further atoms or groups other than R¹, R² and R³ are involved in the respective linkage.

According to the invention, it is preferred that in the ruthenium complex
(arene) is an arene or an arene substituted with 1 to 6 identical or different C₁-C₈ hydrocarbon radicals,
R¹ is selected from H, C₁-C₈ hydrocarbon radical and —NR⁴R⁵, wherein R⁴ and R⁵ are selected independently of one another from H and C₁-C₈ hydrocarbon radicals, and
R² and R³ are selected independently of one another from C₁-C₈ hydrocarbon radicals.

In the preferred ruthenium complex, none of the C₁-C₈ hydrocarbon radicals is substituted. This can lead to an improvement in volatility and liquidity at room temperature.

In cases where (arene) in the preferred ruthenium complex is a substituted arene, the substituents are C₁-C₈ hydrocarbon radicals, more preferably C₁-C₆ hydrocarbon radicals, even more preferably C₁-C₄ hydrocarbon radicals. In these cases, the arene preferably has 1 to 6 substituents, i.e. 1, 2, 3, 4, 5 or 6 substituents, more preferably 2 substituents.

According to the invention, it is preferred for the ligand (arene) to have a benzenoid structure. A cyclic chemical structure in which three double bonds are formally still present within a single six-membered carbon ring is generally referred to as a benzenoid structure. In the context of the present invention, benzene and a benzene substituted with 1 to 6 C₁-C₈ hydrocarbon radicals, preferably with 1 to 6 C₁-C₆ hydrocarbon radicals, more preferably with 1 to 6 C₁-C₄ hydrocarbon radicals, have a benzenoid structure. According to the invention, it is preferred for the ligand (arene) to be coordinated with the ruthenium via such a benzenoid structure, namely via the δdelocalized πelectron system of the benzenoid structure. In the hapto nomenclature customary for complex compounds, such a coordination is referred to as θ⁶ coordination.

According to the invention, it is preferred for (arene) to comprise a benzenoid structure that is coordinated with Ru η⁶. This coordination can contribute to an improved stability of the complex.

According to the invention, it is preferred for L to be coordinated with Ru via the nitrogen of R²N and via the nitrogen of NR³. This coordination can contribute to an improved stability of the complex.

According to the invention, it is preferred for (arene) to simultaneously comprise a benzenoid structure coordinated with Ru η⁶ and for L to be coordinated via the nitrogen of R²N and via the nitrogen of NR³ with Ru. Such simultaneous coordination is shown in the following general reaction scheme. This simultaneous coordination can contribute to an improved stability of the complex.

According to the invention, it is preferred that in the ruthenium complex
(arene) is benzene or benzene substituted with 1 to 6 C₁-C₄ identical or different hydrocarbon radicals,
X is H or C₁-C₄ hydrocarbon radical,
R¹ is H, methyl, ethyl, —N(methyl)₂ or —N(ethyl)₂, and
R², R³ are each a C₁-C₄ hydrocarbon group.

Such a ruthenium complex can be prepared in a few steps under mild conditions.

According to the invention, it is preferred for the ligand (arene) in the ruthenium complex of the general formula (I) to be an arene substituted with hydrocarbon radicals, in particular an arene substituted with different hydrocarbon radicals. According to the invention, it is preferred for (arene) to be substituted with two different hydrocarbon radicals. Without being bound by this theory, it is assumed that a different or asymmetrical substitution of arene with different hydrocarbon radicals, in particular with two different hydrocarbon radicals, such as in 4-isopropyltoluene, will make crystallization of the ruthenium complex more difficult. The asymmetrical substitution of arene can thus contribute to liquidity of the ruthenium complex according to the invention at room temperature.

According to the invention, it is preferred for (arene) to be selected from benzene and benzene substituted with 1 to 6 C₁-C₈ hydrocarbon radicals. According to the invention, it is more preferred for (arene) to be selected from benzene and benzene substituted with 1 to 6 C₁-C₆ hydrocarbon radicals. According to the invention, it is even more preferred for (arene) to be selected from benzene and benzene substituted with 1 to 6 C₁-C₄ hydrocarbon radicals. According to the invention, it is further preferred for (arene) to be selected from benzene and 4-isopropyltoluene. 4-isopropyltoluene is also referred to as p-cymene or para-cymene. Benzene and substituted benzene, in particular 4-isopropyltoluene, as (arene) can yield stable ruthenium complexes according to the invention.

According to the invention, it is preferred for the ligand X to be selected from H and a C₁-C₆ hydrocarbon radical, more preferably from H and a C₁-C₄ hydrocarbon radical. According to the invention, it is particularly preferred for the ligand X to be selected from hydrido ligand (H), methyl (Me), ethyl (Et), propyl (Pr), isopropyl (IPPr) and tert-butyl (tBu). X is more preferably selected from H, methyl and ethyl. In a preferred embodiment, X is H. In a further preferred embodiment, X is methyl. In yet another preferred embodiment, X is ethyl. The smaller and lighter the ligand X, the more volatile and more easily liquid at room temperature the corresponding ruthenium complexes can be.

According to the invention, it is preferred for R¹ of the ligand L to be selected from methyl and —N(methyl)₂. The present invention will sometimes also refer to the dimethylamino group —N(methyl)₂ as NMe₂. Methyl and —N(methyl)₂ as R¹ can contribute to introducing the ligand L synthetically more easily into ruthenium complex intermediates.

According to the invention, R² and R³ are selected independently of one another from C₁-C₈ hydrocarbon radicals, preferably C₁-C₆ hydrocarbon radicals, more preferably C₁-C₄ hydrocarbon radicals. The hydrocarbon radicals may be optionally substituted, for example with amino groups. According to the invention, it is preferred that neither R² nor R³ comprise amino groups. This can lead to better volatility and liquidity at room temperature.

According to the invention, it is preferred for R² and R³ to be selected independently of one another from methyl, ethyl, propyl, isopropyl and tert-butyl. The smaller and lighter the radicals R² and R³, the more volatile and more easily liquid at room temperature the corresponding ruthenium complexes can be.

According to the invention, it may be preferred for R² and R³ to be the same. According to the invention, it may be particularly preferred for both R² and R³ to be isopropyl. If R² and R³ are the same, and in particular are both isopropyl, the ligand L can be introduced better as metal organyl in ruthenium complex intermediates.

According to the invention, it may be preferred for R² and R³ to be different from one another; for example, R² is ethyl and R³ is tert-butyl. This results in an unsymmetrical structure of L. An unsymmetrical structure of L can contribute to preventing solidification of the ruthenium complex at room temperature.

According to the invention, it may be preferred for R¹ to not be directly linked to R², R¹ to not be directly linked to R³ and R² to not be directly linked to R³, i.e. that the ligand L has no corresponding cyclic groups. This can reduce the number of steps required for synthesizing the ruthenium complexes according to the invention.

According to the invention, it may be preferred for R¹ and R² to be directly linked to one another. According to the invention, it may be preferred for R¹ and R³ to be directly linked to one another. According to the invention, it may be preferred for R² and R³ to be directly linked to one another. According to the invention, it may be preferred for both R¹ and R² as well as R¹ and R³ to be directly linked to one another, for both R¹ and R² as well as R² and R³ to be directly linked to one another, for both R¹ and R³ as well as R² and R³ to be directly linked to one another, and for R¹ and R², R¹ and R³ as well as R² and R³ to be directly linked to one another. This can increase the variability of the synthesis of the ruthenium complexes according to the invention.

According to the invention, it is preferred for the ruthenium complex to be liquid under standard conditions. Standard conditions are a temperature of 25° C. and an absolute pressure of 1·10⁵ Pa. The aggregate state “liquid” includes an oily consistency of the ruthenium complex. Liquidity of the ruthenium complex under standard conditions can improve the suitability of the ruthenium complex for CVD and ALD processes.

According to the invention, it is preferred for the ruthenium complex to not be present as a solid. According to the invention, it is particularly preferred for the ruthenium complex to have a melting point of ≤25° C. at an absolute pressure of 1.013·10⁵ Pa, more preferably ≤10° C., more preferably ≤0° C. Such a ruthenium complex may be better suited for CVD and ALD processes.

A ruthenium complex according to the invention preferably cannot be isolated by filtration and/or sublimation after synthesis in a solvent. According to the invention, it is preferred for a ruthenium complex according to the invention to be isolable by condensation. According to the invention, it is particularly preferred for the ruthenium complex to be isolable in fine vacuum (FV) by condensation. In the context of the present invention, a fine vacuum comprises a pressure range of 10² to 10⁴ Pa (0.001 to 0.1 bar). Ruthenium complexes that can be isolated by condensation may be better suited for use in CVD and ALD processes.

According to the invention, it is preferred for the ruthenium complex to decompose at temperatures in the range from 100 to 200° C., more preferably in the range from 100 to 150° C. or in the range from 150 to 200° C. Decomposition of the ruthenium complex at these temperatures may improve the suitability of the ruthenium complex for CVD and ALD processes.

According to the invention, it is preferred for the onset of decomposition of a ruthenium complex according to the invention to be determined by thermal analysis. The thermal analysis is preferably a thermogravimetric analysis (TGA). Thermogravimetric analysis is an analytical method in which mass changes of a sample are measured as a function of temperature and time. In the thermogravimetric analysis, the sample is heated in a crucible. A holder of the crucible is coupled to a scale which registers mass changes during the heating process. If a reduction in mass occurs during the heating process, this can point to a disintegration of the sample.

According to the invention, it is preferred for the temperature of an onsetting mass reduction by decomposition-free evaporation, measured in a thermogravimetric analysis (TGA) at 1·10⁵ Pa (1 bar), to be at least 10 to 30° C. below the decomposition point. The TGA typically takes place in a temperature range of 25° C. to 600° C. or 25° C. to 700° C. The heating rate during TGA is typically 10° C./min. Mass reduction caused by evaporation and/or decomposition is preferably tracked by TGA and by simultaneous differential thermal analysis (SDTA). SDTA determines the heat flow using endothermic peaks (e.g. melting point, evaporation from the liquid phase, sublimation below the melting point) or exothermic peaks (e.g. exothermic decomposition reaction). An endothermic peak without loss of mass regularly corresponds to a melting point. An endothermic peak with loss of mass corresponds to evaporation. An exothermic peak with loss of mass corresponds to decomposition. These parameters can be determined experimentally via onset values. What is specified is the temperature of a TGA/SDTA at which the mass of the sample of the ruthenium complex analyzed is reduced by 3 wt % (3% reduction). According to the invention, it is preferred for the temperature of this first mass reduction of 3 wt % of the ruthenium complex at 1·10⁵ Pa to be in the range from 80 to 200° C., more preferably in the range from 80 to 150° C. in a thermogravimetric analysis.

The invention also relates to a method for producing a ruthenium complex according to the invention, the method comprising the following steps:

(i) Reacting a compound of formula R²N═C═NR³ with a compound of formula Li—R¹ to produce a compound of formula Li(R²N—CR¹═NR³),
(ii) Reacting the compound Li(R²N—CR¹═NR³) with a compound of formula [RuCl₂(arene)]₂ to produce a compound of formula [(arene)RuCl(R²N—CR¹═NR³)], and
(iii) Reacting the compound [(arene)RuCl(R²N—CR¹═NR³)] with a compound MXₙ, wherein M=metal and n=1, 2, 3 or 4.

In the method according to the invention, steps (i), (ii) and (iii) take place in the order indicated. Here, it is particularly preferred for the compound Li(R²N—CR¹═NR³) to be formed in situ and reacted directly with a compound of formula [RuCl₂(arene)]₂. In other words, the compound Li(R²N—CR¹═NR³) is not isolated prior to reaction with the compound [RuCl₂(arene)]₂.

According to the invention, it is preferred for MXₙ to be selected from LiAlH₄, MeLi or EtMgBr.

The invention also relates to the use of a ruthenium complex according to the invention for depositing ruthenium in a CVD process or an ALD process.

The invention also relates to a method in which a ruthenium complex according to the invention is used as a precursor for producing a ruthenium layer.

The invention also relates to a ruthenium-plated surface obtainable by depositing ruthenium on a surface from a gas phase. The gas phase comprises a ruthenium complex according to the invention.

### General Synthetic Scheme

The synthesis of a ruthenium complex according to the invention can be carried out via the respective ruthenium chloride compound [(arene)RuClL] followed by substitution of Cl by an alkyl group, such as Me, Et or a hydrido ligand H.

The preparation of the chloride intermediates is achieved, for example, in a one-pot synthesis from the lithium salt of a guanidinate, preferably formed in situ via the addition of a secondary lithium amide, such as LiNMe₂ to a carbodiimide R²N═C═NR³ (R², R³=iPr or other, also different alkyl group) and reaction of the reaction solution with compounds of the type [RuCl₂(arene)]₂. For amidinates, the one-pot synthesis from the lithium salt of the amidinate, optionally formed in situ is achieved by addition of a lithium organyl LiR¹ (preferably R¹=Me) to a carbodiimide R²N═C═NR³ (R², R³=iPr or other alkyl group) and reaction of this reaction solution with compounds of the type [RuCl₂(arene)]₂. The subsequent substitution of Cl is achieved without great synthetic effort by reaction with, for example, LiAlH₄, MeLi or EtMgBr. A one-pot synthesis starting from [RuCl₂(arene)]₂ without necessary isolation of the chloride intermediate is possible when using solutions of the reactants of exactly known contents.

Possible synthesis routes for ruthenium complexes according to the invention are summarized in the following general reaction scheme:

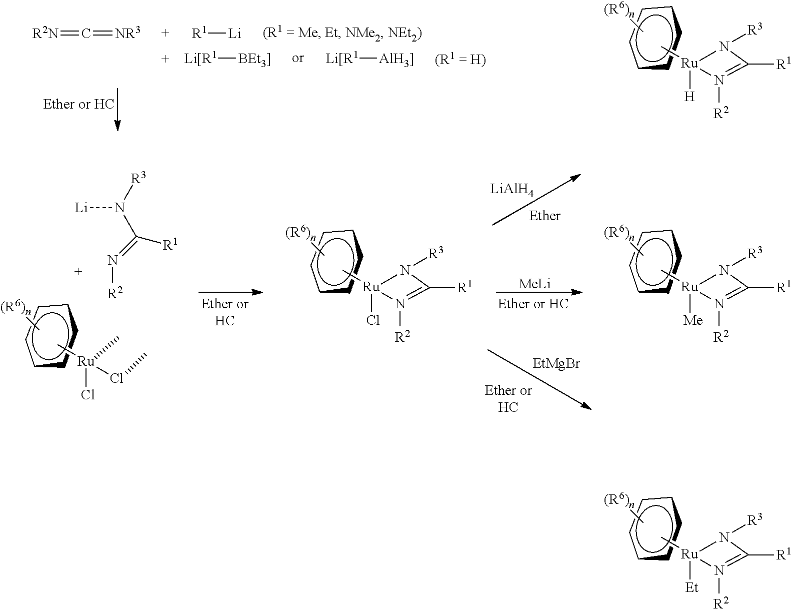

In the reaction scheme, the radicals R¹, R², R³ and R⁶ are as described herein.

The reaction steps in the scheme can be carried out in ethers, preferably diethyl ether (Et₂O) or tetrahydrofurane (THF), optionally also in a mixture with hydrocarbons (HC), such as hexane or toluene, in each case at 0° C. After removal of the solvent, the chloride complexes can be extracted in vacuo with nhexane and obtained by sublimation in purest form. However, isolation of the intermediate is not mandatory since a solvent change also is not mandatory for the last step.

The exemplary substitution of the chloride ligand at the ruthenium proceeds with a Grignard reagent for introducing the ethyl group, with MeLi for introducing the methyl group and with LiAlH₄ for introducing the hydride. The use of Red-Al® (Na[H₂Al(OCH₂CH₂OMe)₂]), LiBH₄ and Li[HBEt₃] for preparation of the hydride target compounds is also conceivable. The substitutions of the chloride ligand are advantageously carried out at 0° C. and, after processing (e.g. extraction with nhexane, filtration via CELITE®), evaporation of the solvent and optionally purification by condensation, typically provide yellowish volatile oils.

### Applications for the Complexes According to the Invention

The ruthenium complexes according to the invention are used as precursors for ruthenium or ruthenium layers. They can be used in particular for the production of thin layers from ruthenium by means of gas-phase thin-film methods, such as CVD and ALD.

Chemical vapor deposition (CVD) is a gas phase reaction that generally takes place at or near a surface of a substrate. Reactants or precursors involved in the reaction are fed to the substrate to be coated in the form of gases. The substrate is arranged in a reaction chamber and is heated. The mostly preheated gases are thermally activated by the heated substrate and react with each other or the substrate. Precursors contained in the gases are thermally decomposed by the heated substrate. Thereby, the desired material is deposited and chemically bonded. Chemisorption of the desired material occurs, i.e. of the ruthenium in the present invention.

The ALD process, also referred to as atomic layer deposition, is a modified CVD process. With the ALD process, the reaction or sorption at the surface ceases after complete occupancy of the surface. This self-limiting reaction is carried out in several cycles with rinsing steps in between. Very precise layer thicknesses are achieved this way.

As described above, the ruthenium complexes according to the invention can be prepared by technical synthesis that requires only little effort. Simple technical synthesis is an important advantage in an industrial application of the ruthenium complexes according to the invention in vapor deposition processes. Another important reason for the particular suitability of the ruthenium complexes according to the invention for CVD and/or ALD processes is that the ruthenium complexes according to the invention are volatile compounds which are partially liquid at room temperature. In addition, they can be successfully decomposed into the corresponding elemental ruthenium. Therefore, when it comes to the deposition of elemental ruthenium, they constitute an advantageous alternative to known ruthenium precursors.

This is also demonstrated by the following examples, in particular by the results of the thermogravimetric and powder diffractometric analyses carried out in this context. For some of the compounds, the analyses by means of TGA/SDTA initially show that they are liquid at 25° C. and do not have melting points above 25° C. In addition, it is clear that compounds having X=Me and H may be vaporized undecomposed at pressures of 1·10⁵ Pa or less. Furthermore, decomposition of such compounds is possible at below 200° C. X-ray powder diffractometry (X-RPD) enables the residue in the crucible to be examined for microcrystalline phases in the powder after decomposition during thermogravimetric analysis. An observed result according to the invention is the detection of the formation of a known phase of elemental ruthenium. The phase is detected by a comparison of the pattern found experimentally at reflexive angles with the data for ruthenium from a reflexive angle database. The formation of a known phase of elemental ruthenium may indicate a particular suitability for CVD and/or ALD processes.

The invention can therefore also be used by methods for depositing ruthenium comprising the steps of
Providing at least one compound according to the invention;
Subjecting said compound to a CVD process or an ALD process.

### EXEMPLARY EMBODIMENTS

In the following examples:
bima: N,N′-bis(isopropylamino)acetamidinate
bidmg: N,N′-bis(isopropylamino)-N″-dimethylguanidinate
dmfa: N,N′-dimethylformamidinate

### Example 1 (Reference)—Preparation and Characterization of Li(Bima)^{[1]}

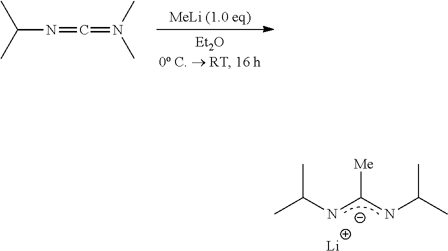

N,N-di-iso-propylcarbodiimide (4.20 g, 33.3 mmol, 1.0 eq) was provided in Et₂O (50.0 ml) and MeLi (in Et₂O, 1.60 ml, 33.3 mmol, 1.0 eq) was added dropwise at 0° C. The reaction mixture was stirred for 16 hours, allowing it to reach room temperature. After removing all volatile components in a fine vacuum, the residue was washed with nhexane (2-20 ml) and dried in a fine vacuum. Li(bima) was obtained as a colorless solid (3.62 g, 24.3 mmol, 73%).

¹H-NMR (THF-d₈, 300.2 MHz): δ/ppm=3.42 (sept, 2 H, ⁱPr), 1.75 (s, 3H, Me), 0.96 (d, ³J_{HH}=6.2 Hz, 12 H, ⁱPr).

¹³C-NMR (THF-d₈, 75.5 MHz): δ/ppm=168.6 (C_{q}), 47.6 (ⁱPr), 27.3 (ⁱPr), 10.4 (Me).

Ultimate analysis C₈H₁₇N₂Li (148.18 g/mol)
calculated: C: 64.85%, H: 11.56%, N: 18.91%
found: C: 63.20%, H: 11.21%, N: 18.46%.

IR (substance) N/cm-1=2958 (m), 2926 (m), 2861 (m), 1484 (vs), 1416 (s), 1373 (m), 1356 (m), 1332 (s), 1311 (s), 1170 (m), 1123 (m), 1047 (w), 1013 (m), 975 (w), 940 (w), 822 (w), 790 (w), 611 (w), 501 (m), 443 (w).

### Example 2 (Reference)—Preparation and Characterization of [RuCl(p-cymene)(bidmg)]

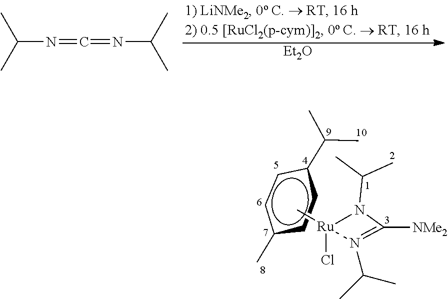

LiNMe₂ (83.1 mg, 1.63 mmol, 2.00 eq) was provided in THE (80 ml) and N,N-diisopropylcarbodiimide (206 mg, 1.63 mmol, 2.00 eq) was added at 0° C. The mixture was stirred for 16 hours, allowing it to warm to room temperature. [Ru(p-cymene)Cl₂]₂ (500 mg, 0.82 mmol, 1.00 eq) was added to the clear, colorless solution and it was stirred again for 16 hours. After removing all volatile components in vacuo, the residue was absorbed in nhexane (50 ml) and filtered over CELITE®. The filter cake was extracted with further amounts of nhexane (30 ml) and the filtrate freed of the solvent in vacuo. The yellow-orange crystalline product (6.25 g, 14.2 mmol, 91%) could furthermore be further purified by sublimation (FV/70° C.), as a result of which the target compound could ultimately be isolated as a yellow-orange solid (1.92 g, 4.36 mmol, 28%).

¹H-NMR C₆D₆, 300.2 MHz: δ/ppm=4.99 (d, ³J_{HH}=5.8 Hz, 2 H, H−5), 4.77 (d, ³J_{HH}=5.8 Hz, 2 H, H−6), 3.61 (sept, 2 H, H−1), 2.60 (sept, 1 H, H−9), 2.45 (s, 6H, NMe₂), 2.07 (s, 3H, H−8), 1.43 (d, ³J_{HH}=6.6 Hz, 6 H, ⁱPr), 1.26 (d, ³J_{HH}=6.3 Hz, 6 H, ⁱPr), 1.06 (d, ³J_{HH}=7.3 Hz, 6 H, ⁱPr).

¹³C-NMR C₆D₆, 75.5 MHz: δ/ppm=166.8 (C-3), 97.9 (C-4), 97.7 (C-7), 79.1 (C-6), 79.0 (C-5), 47.5 (C-1), 40.6 (NMe₂), 32.5 (C-10), 26.7 (C-2), 25.6 (C-2), 22.7 (C-8), 19.4 (C-9).

HR-EI(+)-MS Calculated for [M+H]⁺=441.1485 m/z, found: 441.1488 m/z.

Ultimate analysis C₁₉H₃₄N₃ClRu (441.02 g/mol)
calculated: C: 51.75%, H: 7.77%, N: 9.53%
found: C: 51.93%, H: 7.85%, N: 10.13%.

IR (substance) \tilde{v}/cm⁻¹=2956 (s), 2919 (m), 2861 (m), 2789 (w). 1610 (w), 1494 (vs), 1448 (s), 1419 (m), 1371 (m), 1357 (m), 1321 (s), 1199 (s), 1165 (m), 1141 (m), 1115 (w), 1091 (s), 1057 (w), 1004 (w), 973 (m), 933 (m), 849 (w), 802 (w), 753 (w), 706 (w), 667 (w), 544 (w), 446 (w).

TGA (T_{S}=25° C., T_{E}=700° C., 10° C./min, m=9.40 mg) steps: 1, T=155.1° C. (3% reduction), T=183.6° C., (max. reduction rate), total mass reduction: 4.83 mg (51.4%).

SDTA (T_{S}=25° C., T_{E}=700° C., 10° C./min, m=9.40 mg) T_{M}(onset)=77.0° C., T_{M}(max)=81.0° C. (endothermic), T_{D}(onset)=174.4° C., T_{D}(max.)=182.9° C. (exothermic).

### Example 3—Preparation and Characterization of [RuMe(p-cymene)(bidmg)]

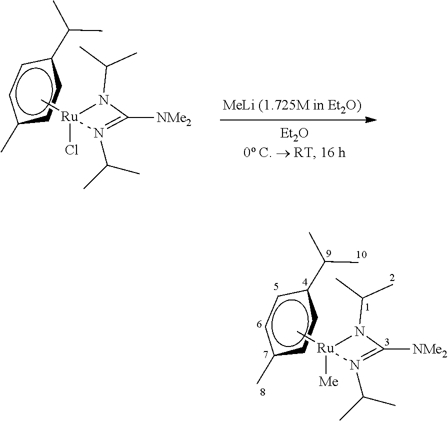

[RuCl(p-cymene)(bidmg)] (300 mg, 0.68 mmol, 1.00 eq) was dissolved in Et₂O (20 ml) at 0° C. and added with a methyllithium solution (1.725 M in Et₂O, 1.17 ml, 0.68 mmol, 1.0 eq) in Et₂O (5 ml). The mixture was stirred for 16 hours, allowing it to slowly warm to room temperature. The volatile components of the clear, light yellow solution were then removed in vacuo, the residue was taken up in nhexane (10 ml) and filtered over a syringe filter. The filtrate was freed of the solvent in vacuo and the gel-like raw product was recondensed (FV/45° C.). The target compound was isolated as a yellow-orange viscous liquid (120 mg, 0.29 mmol, 43%).

¹H-NMR C₆D₆, 300.2 MHz: δ/ppm=4.90 (d, ³J_{HH}=5.5 Hz, 2 H, H−5), 4.26 (d, ³J_{HH}=5.7 Hz, 2 H, H−6), 3.67 (sept, 2 H, H−1), 2.65 (sept, 2 H, H−9), 2.50 (s, 6H, NMe₂), 2.02 (s, 3H, H−8), 1.21 (d, ³J_{HH}=7.1 Hz, 6 H, ⁱPr), 1.16 (d, ³J_{HH}=6.3 Hz, 6 H, Pr), 0.97 (d, ³J_{HH}=6.5 Hz, 6 H, Pr), 0.89 (s, 3H, RuMe).

¹³C-NMR C₆D₆, 75.5 MHz: δ/ppm=160.2 (C-3), 106.8 (C-4), 95.8 (C-7), 81.0 (C-6), 73.2 (C-5), 46.8 (C-1), 41.1 (NMe₂), 32.9 (C-10), 26.2 (C-2), 25.0 (C-2), 23.7 (C-8), 18.7 (C-9), 6.73 (RuMe).

HR-EI(+)-MS Calculated for [M+H]⁺=421.2031 m/z, found: 421.2017 m/z.

Ultimate analysis C₂₀H₃₇N₃Ru (420.61 g/mol)
calculated: C: 57.11%, H: 8.87%, N: 9.99%
found: C: 57.07%, H: 8.75%, N: 10.79%.
Due to the liquid aggregate state of the compound, the samples had to be included in additional outer crucibles for ultimate analysis, which leads to the inclusion of more nitrogen and consequently to corruption of this measured value.

IR (substance) \tilde{v}/cm⁻¹=3051 (m), 2959 (m), 2924 (m), 2787 (w), 1504 (vs), 1447 (s), 1417 (m), 1373 (m), 1354 (m), 1328 (s), 1280 (w), 1203 (s), 1163 (s), 1145 (s), 1116 (m), 1084 (w), 1055 (s), 1004 (w), 969 (m), 835 (m), 802 (m), 655 (w), 540 (w), 503 (w), 446 (w).

TGA (T_{S}=25° C., T_{E}=600° C., 10° C./min, m=10.0 mg) steps: 1, T=166.7° C. (3% reduction), T=198.9° C. (max. reduction rate), total mass reduction: 5.92 mg (59.2%).

SDTA (T_{S}=25° C., T_{E}=600° C., 10° C./min, m=9.40 mg) T_{D}(onset)=160.4° C., T_{D}(max.)=196.1° C. (exothermic).

### Example 4—Preparation and Characterization of [RuH(p-cymene)(bidmg)]

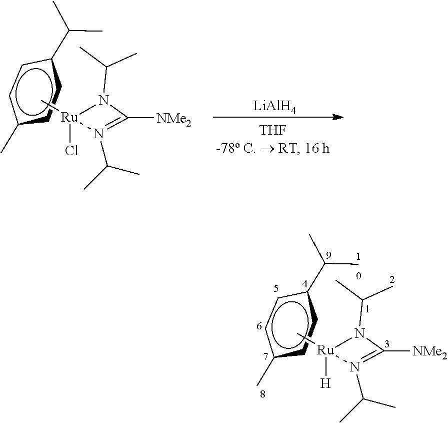

[RuCl(p-cymene)(bidmg)] (0.40 g, 0.91 mmol, 1.00 eq) and LiAlH₄ (10.0 mg, 0.27 mmol, 0.30 eq) were provided together and suspended in THE (20 ml) at −78° C. The mixture was stirred for 16 hours, allowing it to slowly warm to room temperature. The volatile components were removed in vacuo, the residue taken up in nhexane (10 ml) and filtered over CELITE®. The filtrate was freed of the solvent in vacuo and the target compound condensed out of the residue (FV/45° C.), wherein it was possible to isolate [RuH(p-cymene)(bidmg)] as an intensively yellow liquid (0.17 g, 0.42 mmol, 46%).

¹H-NMR C₆D₆, 300.2 MHz: δ/ppm=4.83 (d, ³J_{HH}=5.0 Hz, 2 H, H−5), 4.73 (d, ³J_{HH}=5.3 Hz, 2 H, H−6), 3.52 (sept, 2 H, H−1), 2.61 (sept, 2 H, H−9), 2.41 (s, 6H, NMe₂), 2.20 (s, 3H, H−8), 1.32 (d, ³J_{HH}=7.1 Hz, 6 H, ⁱPr), 1.16 (d, ³J_{HH}=6.1 Hz, 6 H, ⁱPr), 1.01 (d, ³J_{HH}=6.6 Hz, 6 H, ⁱPr), −4.66 (s, 1H, RuH).

¹³C-NMR C₆D₆, 75.5 MHz: δ/ppm=160.1 (C-3), 105.7 (C-4), 96.7 (C-7), 77.0 (C-6), 76.2 (C-5), 46.2 (C-1), 40.2 (NMe₂), 33.4 (C-10), 26.5 (C-2), 25.6 (C-2), 24.2 (C-8), 21.2 (C-9).

HR-EI(+)-MS Calculated for [M+H]⁺=407.1875 m/z, found: 407.1888 m/z.

Ultimate analysis C₁₉H₃₅N₃Ru (406.56 g/mol)
calculated: C: 56.13%, H: 8.68%, N: 10.34%
found: C: 56.36%, H: 8.67%, N: 11.23%.
Due to the liquid aggregate state of the compound, the samples had to be included in additional outer crucibles for ultimate analysis, which leads to the inclusion of more nitrogen and consequently to corruption of this measured value.

IR (substance) \tilde{v}/cm⁻¹=3052 (w), 2959 (vs), 2918 (s), 2864 (s), 2788 (m), 1884 (m), 1638 (w), 1493 (vs), 1445 (s), 1411 (s), 1371 (m), 1352 (m), 1329 (m), 1282 (w), 1198 (s), 1166 (m), 1142 (m), 1117 (m), 1083 (w), 1054 (vs), 1004 (w), 971 (m), 834 (s), 803 (m), 677 (m), 539 (m), 444 (w).

TGA (T_{S}=25° C., T_{E}=600° C., 10° C./min, m=15.1 mg) steps: 1, T=119.5° C. (3% reduction), T=167.6° C., (max. reduction rate), total mass reduction: 7.55 mg (50.0%).

SDTA (T_{S}=25° C., T_{E}=600° C., 10° C./min, m=15.1 mg) T_{D}(onset)=161.0° C., T_{D}(max.)=169.7° C. (exothermic).

### Example 5 (reference)—Preparation and Characterization of [RuCl(p-cymene)(bima)]^{[2]}

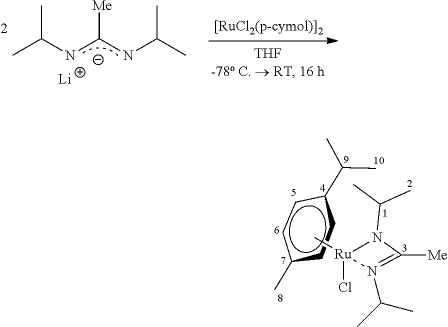

Li(bima) (403 mg, 2.70 mmol, 2.3 eq) was provided in THE (20 ml) and [RuCl₂(p-cymene)]₂ (735 mg, 1.20 mmol, 1.0 eq) was added at −78° C. The mixture was stirred for 16 hours, wherein it reached room temperature and took on a deep red color. After removing all volatile components in a fine vacuum, the residue was suspended in nhexane (20 ml) and filtered over CELITE®. The filter cake was extracted with further amounts of nhexane (30 ml) and the resulting filtrate was subsequently dried in a fine vacuum. [RuCl(p-cymene)(bima)] was obtained as a dark red solid (149 mg, 0.45 mmol, 29%) by means of sublimation (FV/120° C.).

¹H-NMR (C₆D₆, 300.2 MHz): 4.97 (d, ³J_{HH}=5.9 Hz, 2 H, H−5), 4.70 (d, ³J_{HH}=5.9 Hz, 2 H, H−6), 3.32 (sept, 2 H, H−1), 2.64 (sept, 1 H, H−9), 2.06 (s, 3H, H−8), 1.38 (d, ³J_{HH}=5.7 Hz, 6 H, ⁱPr), 1.38 (s, 3H, Me), 1.18 (d, ³J_{HH}=6.7 Hz, 6 H, Pr), 1.10 (d, ³J_{HH}=6.8 Hz, 6 H, ⁱPr).

¹³C-NMR (C₆D₆, 75.5 MHz): δ/ppm=173.5 (C-3), 98.4 (C-4), 97.6 (C-7), 79.2 (C-6), 78.6 (C-5), 48.0 (C-1), 32.4 (Me), 26.2 (C-10), 25.9 (C-2), 22.8 (C-2), 19.3 (C-8), 13.5 (C-9).

HR-EI(+)-MS calculated for: [M]⁺=412.1220 m/z, found: 441.1219 m/z.

Ultimate analysis C₁₈H₃₁N₂ClRu (406.56 g/mol)
calculated: C: 52.48%, H: 7.58%, N: 6.80%
found: C: 52.32%, H: 7.39%, N: 6.50%.

IR (substance) \tilde{v}/cm⁻¹=2955 (s), 2922 (m), 2861 (m), 2593 (w), 1507 (s), 1468 (m), 1447 (m), 1422 (m), 1373 (m), 1358 (m), 1331 (vs), 1310 (m), 1275 (m), 1213 (s), 1169 (m), 1143 (m), 1119 (m), 1089 (m), 1054 (m), 1012 (m), 928 (w), 885 (w), 847 (m), 803 (m), 732 (w), 703 (w), 662 (w), 630 (w), 577 (w), 548 (w), 521 (w), 483 (w), 445 (w).

TGA (T_{S}=25° C., T_{E}=700° C., 10° C./min, m=9.75 mg) steps: 1, T=179.3° C. (3% reduction), T_{MA}=205.8° C. (1st process), T_{MA}=292.5° C. (2nd process), total mass reduction: 7.32 mg (75.0%).

SDTA (T_{S}=25° C., T_{E}=700° C., 10° C./min, m=9.75 mg) T_{M}(onset)=61.0° C., T_{M}(max)=65.0° C. (endothermic), T_{D1}(onset)=186.3° C., T_{D1}(max)=189.2° C. (endothermic), T_{D2}(onset)=202.1° C., T_{D2}(max)=210.0° C. (exothermic).

### Example 6—Preparation and Characterization of [RuMe(p-cymene)(bima)]

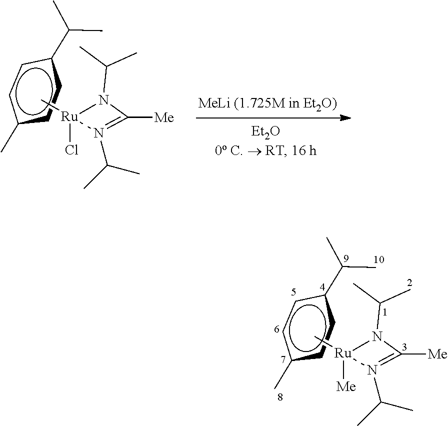

[RuCl(p-cymene)(bima)] (632 mg, 1.53 mmol, 1.0 eq) was provided in Et₂O (20 ml) and MeLi (1.725 M in Et₂O, 0.96 ml, 1.53 mmol, 1.0 eq) was added at 0° C. The mixture was stirred for 16 hours, allowing it to reach room temperature, and was then filtered over CELITE®. The filter cake was extracted with further amounts of Et₂O (15 ml) and the filtrate freed of all volatile components in a fine vacuum. Condensation (FV/110° C.) was used to isolate [RuMe(p-cymene)(bima)] from the residue as a yellow oil (216 mg, 0.55 mmol, 36%).

¹H-NMR (C₆D₆, 300.2 MHz): 4.85 (d, ³J_{HH}=5.7 Hz, 2 H, H−5), 4.21 (d, ³J_{HH}=5.7 Hz, 2 H, H−6), 3.37 (sept, 2 H, H−1), 2.70 (sept, 1 H, H−9), 2.04 (s, 3H, Me), 1.42 (s, 3H, H−8), 1.23 (d, ³J_{HH}=7.2 Hz, 6 H, ⁱPr), 1.11 (d, ³J_{HH}=6.5 Hz, 6 H, ⁱPr), 1.05 (s, 3H, RuMe), 0.91 (d, ³J_{HH}=6.5 Hz, 6 H, ⁱPr).

¹³C-NMR (C₆D₆, 75.5 MHz): δ/ppm=164.7 (C-3), 106.8 (C-4), 96.7 (C-7), 80.7 (C-6), 72.9 (C-5), 47.5 (C-1), 32.7 (Me), 26.1 (C-10), 25.2 (C-2), 23.8 (C-2), 18.7 (C-8), 12.2 (C-9), 5.39 (RuMe).

HR-EI(+)-MS calculated for: [M]⁺=392.1766 m/z, found: 392.1751 m/z.

Ultimate analysis C₁₉H₃₄N₂Ru (391.57 g/mol)
calculated: C: 58.28%, H: 8.75%, N: 7.15%
found: C: 57.59%, H: 8.67%, N: 11.30%.
Due to the liquid aggregate state of the compound, the samples had to be included in additional outer crucibles for ultimate analysis, which leads to the inclusion of more nitrogen and consequently to corruption of this measured value.

IR \tilde{v}/cm⁻¹=3052 (w), 2958 (vs), 2924 (s), 2865 (s), 2791 (w), 2594 (w), 1651 (w), 1521 (vs), 1447 (m), 1373 (m), 1356 (m), 1329 (s), 1274 (w), 1217 (s), 1168 (m), 1145 (m), 1116 (m), 1083 (w), 1054 (m), 1012 (m), 921 (w), 886 (w), 836 (m), 803 (w), 655 (w), 628 (w), 567 (w), 545 (w), 501 (w), 443 (w), 420 (w).

TGA (T_{S}=25° C., T_{E}=600° C., 10° C./min, m=8.48 mg) steps: 1, T=147.3° C. (3% reduction), T_{MA}=228.4° C., total mass reduction: 6.67 mg (78.6%).

SDTA (T_{S}=25° C., T_{E}=600° C., 10° C./min, m=8.48 mg) T_{D}(onset)=224.4° C., T_{D}(max)=231.5° C. (exothermic).

### Example 7—Preparation and Characterization of [RuH(p-Cymene)(Bima)]

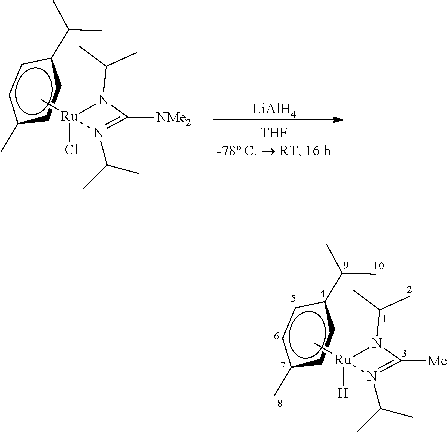

[RuCl(p-cymene)(bima)](440 mg, 1.07 mmol, 1.0 eq) and LiAlH₄ (20.0 mg, 0.53 mmol, 0.5 eq) were provided in THE (40 ml) at −78° C. and stirred for a period of 16 hours, allowing the mixture to reach room temperature. It was then additionally heated under reflux conditions for 24 hours to complete the conversion. All volatile components were removed in a fine vacuum and the residue taken up in nhexane (15 ml) and filtered over CELITE®. The filter cake was extracted with further amounts of nhexane (10 ml) and the filtrate was subsequently freed of the solvent in a fine vacuum. The compound [RuH(p-cymene)(bima)] was condensed out of the residue in a fine vacuum at 100° C. as a brown oil (117 mg, 0.31 mmol, 29%).

¹H-NMR (C₆D₆, 300.2 MHz): 4.78 (d, ³J_{HH}=5.7 Hz, 2 H, H−6), 4.71 (d, ³J_{HH}=5.6 Hz, 2 H, H−5), 3.23 (sept, 2 H, H−1), 2.64 (sept, 1 H, H−9), 2.22 (s, 3H, Me), 1.34 (d, ³J_{HH}=6.9 Hz, 6 H, ⁱPr), 1.30 (s, 3H, H−8), 1.26 (d, ³J_{HH}=6.4 Hz, 6 H, ⁱPr), 1.13 (d, ³J_{HH}=6.3 Hz, 6 H, ⁱPr), −3.99 (s, 1H, RuH).

¹³C-NMR (C₆D₆, 75.5 MHz): δ/ppm=165.7 (C-3), 105.4 (C-4), 97.7 (C-7), 77.1 (C-6), 75.4 (C-5), 47.1 (C-1), 33.4 (Me), 26.4 (C-10), 25.5 (C-2), 24.4 (C-2), 21.3 (C-8), 10.9 (C-9).

Ultimate analysis C₁₈H₃₂N₂Ru (377.54 g/mol)
calculated: C: 57.27%, H: 8.54%, N: 7.42%
found: C: 57.45%, H: 8.41%, N: 10.05%.
Due to the liquid aggregate state of the compound, the samples had to be included in additional outer crucibles for ultimate analysis, which leads to the inclusion of more nitrogen and consequently to corruption of this measured value.

IR \tilde{v}/cm⁻¹=3052 (w), 3052 (vs), 2960 (m), 2922 (m), 2866 (m), 1878 (m), 1649 (w), 1516 (vs), 1447 (m), 1373 (m), 1355 (m), 1331 (m), 1272 (w), 1217 (m), 1172 (m), 1146 (m), 1118 (m), 1083 (m), 1054 (w), 1016 (m), 835 (m), 812 (m), 678 (w), 624 (w), 594 (w), 544 (m), 478 (w), 448 (w).

TGA (T_{S}=25° C., T_{E}=700° C., 10° C./min, m=10.1 mg) steps: 1, T=130.6° C. (3% reduction), T_{MA}=194.1° C., total mass reduction: 8.39 mg (80.2%).

SDTA (T_{S}=25° C., T_{E}=700° C., 10° C./min, m=6.50 mg) T_{D}(onset)=183.6° C., T_{D}(max)=192.4° C. (exothermic).

### Example 8 (reference)—Preparation and Characterization of [RuCl(benzene)(bidmg)]

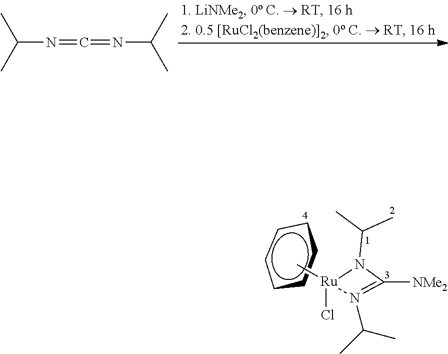

LiNMe₂ (62.4 mg, 1.20 mmol, 1.0 eq) was provided in THE and N,N-di-iso-propylcarbodiimide (151 mg, 1.20 mmol, 1.0 eq) was added at 0° C. The mixture was stirred for 16 hours, allowing it to reach room temperature. After cooling again to 0° C., [RuCl₂(benzene)]₂ (300 mg, 0.60 mmol, 0.5 eq) was added and the mixture was stirred for 16 hours, allowing it to reach room temperature. The suspension was then filtered over CELITE® and the resulting filtrate was dried in a fine vacuum. [RuCl(benzene)(bidmg)] was obtained as a dark red solid (222 mg, 0.56 mmol, 46%) from the residue obtained in the process by means of sublimation (FV/120° C.).

¹H-NMR (C₆D₆, 300.2 MHz): 4.96 (d, 6H, H−6), 3.63 (sept, 2 H, H-1), 2.44 (s, 6H, NMe₂), 1.43 (d, ³J_{HH}=6.4 Hz, 6 H, ⁱPr), 1.27 (d, ³J_{HH}=6.3 Hz, 6 H, ⁱPr).

¹³C-NMR (C₆D₆, 75.5 MHz): δ/ppm=166.8 (C-3), 81.0 (C-4), 47.7 (C-1), 40.5 (NMe₂), 26.3 (C-2), 25.5 (C-2).

HR-EI(+)-MS calculated for: [M]⁺=385.0859 m/z, found: 385.0859 m/z.

Ultimate analysis C₁₅H₂₆N₃ClRu (384.91 g/mol)
calculated: C: 46.81%, H: 6.67%, N: 10.92%
found: C: 47.05%, H: 6.67%, N: 10.85%.

IR (substance) N/cm⁻¹=3053 (m), 2958 (m), 2915 (m), 2857 (m), 2789 (m), 1481 (vs), 1450 (s), 1416 (m), 1373 (m), 1356 (m), 1323 (m), 1194 (m), 1167 (m), 1138 (m), 1118 (m), 1059 (s), 1007 (w), 974 (m), 879 (w), 821 (s), 755 (w), 703 (w), 619 (w), 546 (w), 467 (w), 442 (w).

TGA (T_{S}=25° C., T_{E}=700° C., 10° C./min, m=6.50 mg) steps: 1, T=152.2° C. (3% reduction), T_{MA}=166.7° C. (1st process), T_{MA}=243.3° C. (2nd process), total mass reduction: 3.38 mg (52.0%).

SDTA (T_{S}=25° C., T_{E}=700° C., 10° C./min, m=6.50 mg) T_{M}(onset)=143.9° C., T_{M}(max)=150.0° C. (endothermic), T_{D}(onset)=162.6° C., T_{D}(max)=169.9° C. (exothermic).

RPD (residue from TGA analysis) 2θ_{Lit}^{[44]}/° (2θ_{obs}/°): 38.39 (38.34), 42.13 (42.15), 43.99 (44.01), 58.33 (58.26), 69.41 (69.34), 78.30 (n.b.), 82.22 (81.73), 84.71 (84.58), 85.96 (n.b.), 92.04 (n.b.), 97.09 (n.b.)→detection: elemental ruthenium.

### Example 9—Preparation and Characterization of [RuMe(benzene)(bidmg)]

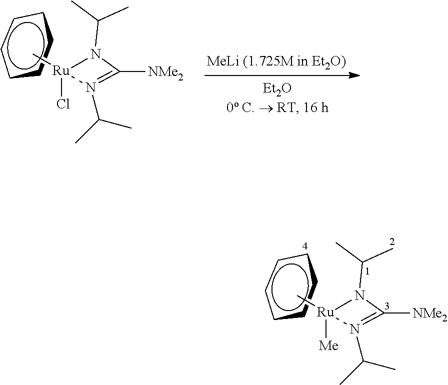

[RuCl(benzene)(bidmg)] (200 mg, 0.52 mmol, 1.0 eq) was provided in THE (10 ml) and a MeLi solution (1.725 M in Et₂O, 0.33 ml, 0.52 mmol, 1.0 eq) was added at 0° C. The mixture was stirred for 16 hours, allowing it to reach room temperature. The filtrate was freed of the solvent in vacuo and the residue taken up in nhexane (10 ml). The suspension was filtered over CELITE® and the filter cake was thereby extracted with further amounts of nhexane (10 ml). After the filtrate had dried in a fine vacuum, the target compound was condensed out of the residue (FV/45° C.), wherein [RuMe(benzene)(bidmg)] was isolated as a brown oil (92.9 mg, 0.25 mmol, 49%) which solidified after a few hours.

¹H-NMR (C₆D₆, 300.2 MHz): 4.82 (s, 6H, H−4), 3.69 (sept, 2 H, H-1), 2.48 (s, 6H, NMe₂), 1.17 (d, ³J_{HH}=6.9 Hz, 6 H, ⁱPr), 0.89 (s, 3H, RuMe), i1.16 (d, ³J_{HH}=6.4 Hz, 6 H, ⁱPr).

¹³C-NMR (C₆D₆, 75.5 MHz): δ/ppm=80.8 (C-4), 46.9 (C-1), 41.0 (NMe₂), 25.8 (C-2), 24.9 (C-2), 2.5 (RuMe). The resonance for the quaternary carbon atom C-3 was not detected in the ¹³C-NMR experiment.

HR-EI(+)-MS calculated for: [M]⁺=365.1405 m/z, found: 365.1416 m/z.

Ultimate analysis C₁₆H₂₉N₃Ru (364.50 g/mol)
calculated: C: 52.72%, H: 8.02%, N: 11.53%
found: C: 53.05%, H: 7.92%, N: 11.46%.

IR \tilde{v}/cm⁻¹=3065 (w), 2957 (m), 2921 (m), 2865 (m), 2785 (m), 1623 (w), 1597 (w), 1497 (vs), 1445 (s), 1415 (m), 1369 (m), 1352 (m), 1328 (m), 1277 (m), 1201 (m), 1162 (m), 1140 (m), 1117 (m), 1053 (s), 968 (m), 858 (w), 799 (w), 780 (m), 697 (w), 608 (w), 539 (w), 506 (w).

TGA (T_{S}=25° C., T_{E}=600° C., 10° C./min, m=5.43 mg) steps: 1, T=152.9° C. (3% reduction), T_{MA}=189.6° C., total mass reduction: 3.61 mg (66.3%).

SDTA (T_{S}=25° C., T_{E}=600° C., 10° C./min, m=5.43 mg) T_{M}(onset)=85.1° C., T_{M}(max)=89.6° C. (endothermic), T_{D}(onset)=180.7° C., T_{D}(max)=193.7° C. (exothermic).

### Example 10 (Reference)—Structural Characterization of [RuCl(p-cymene)(dmfa)]

The complex [RuCl(p-cymene)(dmfa)] may serve as an intermediate for low molecular weight complexes according to the invention. The complex was characterized by X-ray analysis. The position of R¹═H was found in the Fourier analysis.

Crystal data from a single crystal X-ray structure analysis:

| | | |
|---|---|---|
| C₁₃H₂₁N₂ClRu | M = 341.84 g/mol | monoclinic, P2₁/c |
| a = 10.2770(6) Å | b= 16.8754(10) Å | c = 16.2504(10) Å |
| α = 900 | β = 92.336(2)° | γ = 90° |
| V = 2815.9(3) Å³ | Z = 8 | |
| D_{calc} = 1.613 Mg/m³ | μ = 1.284 mm⁻¹ | F(000) = 1392 |
| Habitus: clear yellow blocks | 0.246 · 0.099 · 0.061 mm³ | |

The crystals examined show a correct ultimate analysis for C, H, N and Cl.

### LITERATURE

[1] M. P. Coles, D. C. Swenson, R. F. Jordan, V. G. Young, Organometallics 1997, 16, 5183-5194.
[2] R. García-Álvarez, F. J. Suárez, J. Díez, P. Crochet, V. Cadierno, A. Antiñolo, R. Fernández-Galán, F. Carrillo-Hermosilla, Organometallics 2012, 31, 8301-8311.

1.-17. (canceled)

18. A ruthenium complex of Formula (I):
[(aren)RuXL] Formula (I)
the ruthenium complex comprising the following ligands:
(arene)=arene which may be optionally substituted,
X H or C1-C8 hydrocarbon radical, and
L R²N—CR¹═NR³,
wherein
R¹ is selected from H, C₁-C₈ hydrocarbon radical, which may be optionally substituted, and —NR⁴R⁵, wherein R⁴ and R⁵ are selected independently of one another from H and C₁-C₈ hydrocarbon radicals, which may be optionally substituted,
R² and R³ are selected independently of one another from C₁-C₈ hydrocarbon radicals, which may be optionally substituted, wherein R² and R³ are the same or different from one another, and
R¹ may be linked directly to R², R¹ to R³ and/or R² to R³.

19. The ruthenium complex according to claim 18, wherein
(arene) is an arene or an arene substituted with 1 to 6 identical or different C₁-C₈ hydrocarbon radicals,
R¹ is selected from H, C₁-C₈ hydrocarbon radical and —NR⁴R⁵, wherein R⁴ and R⁵ are selected independently of one another from H and C₁-C₈ hydrocarbon radicals, and
R² and R³ are selected independently of one another from C₁-C₈ hydrocarbon radicals.

20. The ruthenium complex according to claim 18, wherein (arene) comprises a benzenoid structure coordinated with Ru η⁶, and/or wherein L is coordinated with Ru via the nitrogen of R²N and via the nitrogen of NR³.

21. The ruthenium complex according to claim 18, wherein
(arene) is benzene or benzene substituted with 1 to 6 C₁-C₄ identical or different hydrocarbon radicals,
X is H or C₁-C₄ hydrocarbon radical,
R¹ is H, methyl, ethyl, —N(methyl)₂ or —N(ethyl)₂, and
R² and R³ each is a C₁-C₄ hydrocarbon group.

22. The ruthenium complex according to claim 18, wherein (arene) is selected from benzene and 4-isopropyltoluene.

23. The ruthenium complex according to claim 21, wherein (arene) is selected from benzene and 4-isopropyltoluene.

24. Ruthenium complex according to claim 18, wherein X is selected from the group consisting of H, methyl, ethyl, propyl, isopropyl and tert-butyl.

25. The ruthenium complex according to claim 18, wherein R¹ is selected from the group consisting of methyl and —N(methyl)₂ or wherein R² and R³ are selected independently of one another from the group consisting of methyl, ethyl, propyl, isopropyl and tert-butyl.

26. The ruthenium complex according to claim 18, wherein R¹ is selected from the group consisting of methyl and —N(methyl)₂ and wherein R² and R³ are selected independently of one another from the group consisting of methyl, ethyl, propyl, isopropyl and tert-butyl.

27. The ruthenium complex according to claim 18, wherein R¹ is not directly linked to R², R¹ is not directly linked to R³ and R² is not directly linked to R³.

28. The ruthenium complex according to claim 18, which is liquid under standard conditions at 25° C. and 1·10⁵ Pa and/or which has a melting point of ≤25° C. at a pressure of 1.013·10⁵ Pa and/or which decomposes at temperatures in the range from 100 to 200° C.

29. The ruthenium complex according to claim 18, wherein, in a thermogravimetric analysis, the temperature of a first mass reduction of 3 wt % of the ruthenium complex is in the range from 80 to 200° C. at 1·10⁵ Pa.

30. A method for producing the ruthenium complex according to claim 18, comprising the steps of:
(i) Reacting a compound of formula R²N═C═NR³ with a compound of formula Li—R¹ to produce a compound of formula Li(R²N—CR¹═NR³),
(ii) Reacting the compound Li(R²N—CR¹═NR³) with a compound of formula [RuCl₂(arene)]₂ to produce a compound of formula [(arene)RuCl(R²N—CR¹═NR³)], and
(iii) Reacting the compound [(arene)RuCl(R²N—CR¹═NR³)] with a compound MXₙ, wherein M=metal and n=1, 2, 3 or 4.

31. The method according to claim 30, wherein the compound Li(R²N—CR¹═NR³) is formed in situ and is reacted directly with a compound of formula [RuCl₂(arene)]₂.

32. A precursor for producing a ruthenium layer which comprises the ruthenium complex according to claim 18.

33. Ruthenium-plated surface obtainable by depositing ruthenium on a surface from a gas phase that comprises the ruthenium complex according to claim 18.

34. A method for depositing ruthenium, comprising the steps of:
Providing at least one compound according to claim 18;
Subjecting the compound according to claim 18 to a CVD process or an ALD process.

35. A method for depositing ruthenium, comprising the steps of:
Providing at least one compound according to claim 23;
Subjecting the compound according to claim 23 to a CVD process or an ALD process.
